(19) United States
(12) Patent Application Publication
(10) Pub. No.: US 2010/0029074 A1
(43) Pub. Date: Feb. 4, 2010

(54) Maskless Process for Solder Bump Production

(76) Inventors: John MacKay, San Jose, CA (US); Henry Roskos, Los Gatos, CA (US)

Correspondence Address: FISH & ASSOCIATES, PC;ROBERT D. FISH, 2603 Main Street, Suite 1000, Irvine, CA, 92614-6232, US

(21) Appl. No.: 12/554,223

(22) Filed: Sep. 4, 2009

Related U.S. Application Data
(63) Continuation-in-part of application No. 12/473,530, filed on May 28, 2009.
(60) Provisional application No. 61/056,562, filed on May 28, 2008.

(51) Int. Cl. H01L 21/3205

(52) U.S. Cl. 438/613; 257/E21.295

(57) ABSTRACT

Methods of producing a solder bump are presented. Preferred methods lack a requirement for masking a target substrate. Contemplated methods include forming a well around one or more bond pads on a wafer where the walls of the well are formed by a covering layer material, possibly comprising photoresist or passivation material. The well can be filled with a contact material. Contact material can comprise a solder paste or an under bump metallization layer, which can be placed within the wells as a contact bed for solder balls. A priori prepared solder balls, in solid form or in molten form, can deposited on the contact material to produce the solder bump.

This application is a continuation-in-part of U.S. patent application having Ser. No. 12/473,530 filed on May 28, 2009, which claims the benefit of priority to U.S. provisional application having Ser. No. 61/056,562 filed on May 28, 2008. This and all other extrinsic materials discussed herein are incorporated by reference in their entirety. Where a definition or use of a term in an incorporated reference is inconsistent or contrary to the definition of that term provided herein, the definition of that term provided herein applies and the definition of that term in the reference does not apply.

### FIELD OF THE INVENTION

The field of the invention is wafer processing technologies.

### BACKGROUND

Production of solder bumps on a substrate (e.g., a silicon wafer) can be quite complex, and costly. One of the more costly time-consuming steps for placing solder bumps on a silicon wafer includes depositing multiple photoresist masking layers to ensure deposited material is placed, or is bonded with appropriate features of a semiconductor device. Time and money could be saved by eliminating masking steps, and better quality solder bumps can be made by a priori preparing the bumps.

Co-pending, parent application having Ser. No. 12/473,530 to MacKay et al. titled “Maskless Process for Solder Bumps Production”, filed May 28, 2009, describes solder bump production processes were photoresist masks are not required. The Applicants have since appreciated that photoresist can still play a role in solder ball production while still lacking a requirement of a masking step. Quality of solder bumps can be improved by utilizing a priori prepared bumps. One aspect, among many, of solder bump quality can be characterized by the uniformity of the bump height with respect each other, or by conformity to a desired tolerance.

A great deal of past effort has been directed to solder bump production, as evidenced by the following references:
a. U.S. Pat. No. 5,736,456 to Akram titled “Method of Forming Conductive Bumps on Die for Flip Chip Applications” (April 1998)
b. U.S. Pat. No. 6,264,097 to Sano titled “Method of Forming a Solder Ball” (July 2001)
c. U.S. Pat. No. 6,489,229 to Sheridan et al. titled “Method of Forming a Semiconductor Device Having Conductive Bumps without Using Gold” (December 2002)
d. U.S. Pat. No. 6,622,907 to Fanti et al. titled “Sacrificial Seed Layer Process for Forming C4 Solder Bumps” (September 2003)
e. U.S. Pat. No. 6,974,659 to Su et al. titled “Method of Forming a Solder Ball Using a Thermally Stable Resinous Protective Layer” (December 2005)
f. U.S. Pat. No. 7,132,358 to Jeong et al. titled “Method of Forming Solder Bump with Reduce Surface Defects” (November 2006)
g. U.S. Pat. No. 7,375,032 to Seliger et al. titled “Semiconductor Substrate Thinning Method for Manufacturing Thinned Die” (May 2008)
h. U.S. Pat. No. 7,410,824 to Do et al. titled “Method for Solder Bumping, and Solder-Bumping Structures Produced Thereby” (August 2008).

The above references disclose various aspects of preparing or creating solder bumps that require a great number of complicated steps, including multiple photoresist processing or masking steps to form proper patterns on a substrate. Still, others have attempted to reduce a need for masking steps.

U.S. Pat. No. 5,492,235 to Crafts et al. titled “Process for Single Mask C4 Solder Bump Fabrication” (February 1996) describes a method for removing ball limiting metallurgy layers from the surface of a wafer in the presence of a lead-tin solder bump. Although Crafts discusses methods of improved C4 solder bump production by obviating a need for additional masking step to mask a solder bump while etching a ball limiting metallurgy, Crafts still relies on tradition techniques of reflowing to form a solder bump as opposed to providing an prepared solder bump. The result is that the Crafts approach could result in a poor quality bump.

U.S. Pat. No. 6,570,251 to Akram et al. titled “Solder Bump Metallization Pad and Solder Bump Connections” (May 2003) also seeks to eliminate a masking step. Interestingly, Akram still requires one or more masking steps to create the solder bump, but offers no insight into improving high quality bumps.

Even with the progress made in solder bump production, photoresist or masks are still used. Additionally, known techniques result in non-uniform solder bumps, which can reduce efficiency of flip chip processing. What has yet to be appreciated is that high quality solid bumps can be created without using masking steps. A well can be formed around a bond pad using a suitable covering material. The well can be filled with a solder paste, and an a priori prepared solder ball can placed on the paste. For example, a solid prepared solder ball can be placed directly on the paste, or a solder ball can be applied to the paste as described in co-owned U.S. Pat. No. 7,007,833 titled “Forming Solder Balls on Substrates” (March 2006). Furthermore, the substrate can be planarized to ensure the solder balls have a highly uniform height. Such an approach allows for forming high quality solder balls on a substrate.

Unless the context dictates the contrary, all ranges set forth herein should be interpreted as being inclusive of their endpoints and open-ended ranges should be interpreted to include only commercially practical values. Similarly, all lists of values should be considered as inclusive of intermediate values unless the context indicates the contrary.

Thus, there is still a need for systems, methods, apparatus, configurations, or other solutions that allow for production of high quality solder bumps.

### SUMMARY OF THE INVENTION

The inventive subject matter provides apparatus, systems and methods in which solder bumps can be produced on a wafer. In one aspect, the inventive subject matter includes forming a solder bump on a substrate having a bond pad. In a preferred embodiment, the substrate comprises a silicon wafer, or other semiconductor device, with a well formed around the bond pad by an existing covering layer, where a covering material encroaches at or near to the edge of the bond pad. The covering material forms well walls around the bond pad, where the well walls form an accessible window to an exposed surface of the bond pad. In preferred embodiments, the covering material can include a passivation material or photoresist. An under bump metallization (UBM) layer comprising one or more metallization films can be also be deposited in the well. In some embodiments, a precursor film of the UBM layer can comprises Palladium, Platinum, or other suitable metals in contact with the bond pad. Additional films of the UBM layer can include an electroless plating film possibly of Nickel, or a non-oxidizing film possibly of Gold or Silver. A contact material, preferably solder paste, can be deposited into the well where the contact material is within electrical contact with the bond pad via one or more films of the UBM layer. In some embodiments, the UBM layer can act as the contact material. The contact material can be reflowed to form a non-bump solder tab in the well. An a priori prepared solder ball can be placed on the contact material (e.g., the solder tab) to form the solder bump.

Another aspect of the inventive subject matter includes forming solder bumps on a target substrate by reworking the target substrate. A target substrate having bond pads is provided where surfaces of the substrate are covered by a covering material that forms a well around exposed surfaces of the bond pads. Contact material is deposited into the wells, reflowed, and planarized to ensure the wells have uniform height. If necessary, the steps can be repeated to fill missed wells, fill gaps, or correct other deviations. Repeating the steps two, three, or more times ensures the production process has a high yield.

Yet another aspect of the inventive subject matter includes adding additional covering material, possibly additional photoresist, around a solder bump. The surface of the substrate can be planarized to expose one or more of the solder bumps on the substrate. Planarizing the substrate surface allows for producing solder bumps such that they have a highly uniform height. Additionally, the solder bump can act as a solder tab for additional solder bumps. Naturally, the steps can be repeated as desired without possible reflow steps to build up a desirable solder bump.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWING

FIG. 1 is a schematic of a cross sectional view of a substrate having a bond pad.

FIG. 2 is a schematic illustrating a cross sectional view of an initial step where a well is formed around the bond pad of FIG. 1, where the well walls comprised material from a existing covering layer.

FIG. 3A is a subsequent step showing a cross sectional view where an intermediary metallization layer is applied over the covering layer, and into the well of FIG. 2.

FIG. 3B illustrates a cross section view where an intermediary metallization layer is only applied into the well of FIG. 2.

FIG. 4A is a further step showing a cross sectional view where a contact material is deposited into the well from FIG. 3A.

FIG. 4B illustrates a cross section view where a contact material is deposited into the well from FIG. 3B.

FIG. 5A is illustrates a cross sectional view where the contact material from FIG. 4A has been reflowed to form a solder tab, and excess metallization film has been removed.

FIG. 5B is illustrates a cross sectional view where the contact material from FIG. 4B has been reflowed to form a solder tab.

FIG. 6A is yet a further step showing a cross sectional view where a solder ball is placed on the solder tab from FIG. 5A to form a solder bump.

FIG. 6B is yet a further step showing a cross sectional view where a solder ball is placed on the solder tab from FIG. 5B to form a solder bump.

FIG. 7A illustrates a cross sectional view of a solder bump where the contact material from FIG. 4 has been reflowed.

FIG. 7B illustrates a cross sectional view of the solder bump where an additional covering layer has been added around the solder bump of FIG. 7A and the substrate has been planarized.

FIG. 7C illustrates an additional solder bump placed on the previous solder bump from FIG. 7B.

FIG. 8 is a schematic of method for producing a solder bump.

### DETAILED DESCRIPTION

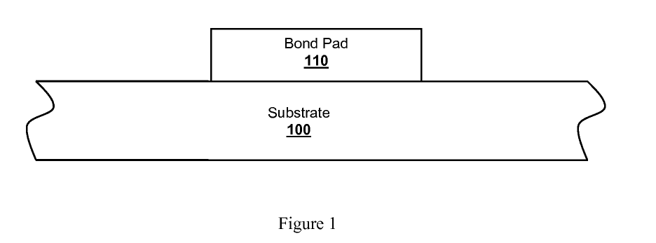

In FIG. 1, shown in cross section, bond pad 110 is disposed on substrate 100. In a preferred embodiment, substrate 100 preferably includes a Silicon (Si) wafer. In fact, herein “substrate” is used euphemistically to represent a surface of a semiconductor device, or the collection of layers as a whole unit. The surface can include a silicon surface or surfaces of layers deposited on the substrate. Bond pad 110 is preferably coupled to substrate 100 using any acceptable known techniques. Bond pad 110 preferably comprises a conductive material. Example acceptable materials include Aluminum (Al), Copper (Cu), AL/Si/Cu, Al/Si, or other metals or their alloys. In a preferred embodiment, bond pad 110 substantially comprises Al.

One should note that in FIG. 1, and the following figures, single bond pad 110 can be considered representative of an array of bond pads 110 disposed on substrate 100. The inventive subject matter is considered to include placing solder bumps on a single bond pad 110 as well as an array of bond pads 110 on substrate 100. It should be further noted, that the disclosed techniques can be applied regardless of the arrangement of bond pads 110, whether they are arranged in a regular pattern, or an irregular arrangement. Furthermore, the disclosed techniques can be used to produce an array of solder bumps having heterogeneous characteristics (e.g., shape, height, width, dimensions, topology, etc.). A preferred embodiment produces an array of solder bumps having homogenous heights.

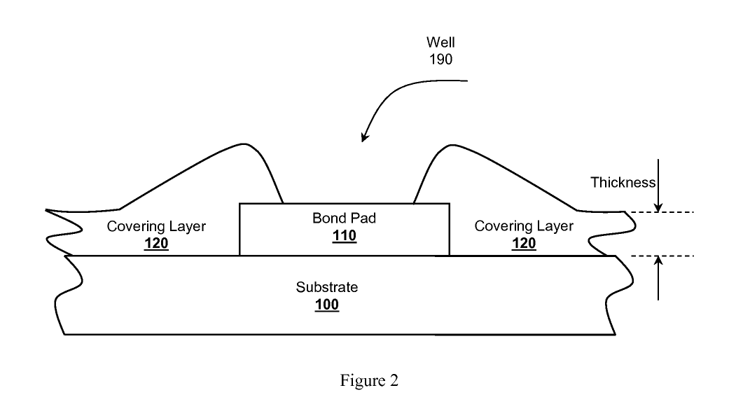

In FIG. 2, also presented in cross section, illustrates a typical starting point for the disclosed inventive subject matter where substrate 100 has been covered with an existing covering layer 120. Typically, organizations or individuals that wish to place solder bumps on such substrates are provided with a wafer having a rather thick covering layer 120 that reaches to the edges of bond pad 110. In a preferred embodiment, covering layer 120 encroaches over the edge of bond pad 110, but leaves well 190 as a window to an exposed surface of bond pad 110. It should be noted that covering layer 120 is not required necessarily to touch bond pad 110.

Covering layer 120 can include various materials capable of forming well 190 and capable of withstanding one or more reflow events. In some embodiments, covering layer 120 can include a passivation layer (e.g., polyimide, a glass, a nitride, etc.). In other embodiments, covering layer 120 can also include a photoresist material that could be removed later. One should note that it is also contemplated that covering layer 120 can comprise a combination of materials, photoresist and passivation materials, for example.

Covering layer 120 can be deposited using known techniques and is preferably created as part of standard integrated circuit manufacturing processes when fabricating components on substrate 100. The disclosed techniques can utilize an existing passivation layer as provided, or possibly a photoresist. It is also contemplated that covering layer 120 can be made thicker to increase the depth of well 190 as desired by depositing additional covering material.

Preferred covering layers 120 have a thickness of roughly 0.5 to 50 micrometers, with a preferred thickness in the range from about 3 to about 5 micrometers. By contrast typical covering layers have a thickness of 0.5 to 2.0 micrometers, and include a via formed from photoresist typically requires a photoresist layer of less than 1 micrometer to prepare for solder bump formation. It is also contemplated that thinner or thicker covering layers could also be used.

Covering layer 120 can comprise one or more various suitable materials. Although covering layer 120 is illustrated as a single layer, one should appreciate that covering layer 120 could comprise multiple layers of deposited materials. For example, covering layer 120 could include an initial glass or nitride passivation layer having a thickness of 0.5 to 2.0 micrometers. Then an additional polyimide passivation layer can be deposited to yield a passivation layer thickness of 5, 10, 20, or more micrometers. It is also contemplated that additional photoresist can be added to increase the thickness of covering layer 120.

In a preferred embodiment, the material used for creating covering layer 120 forms a well wall around exposed surfaces of bond pad 110. The depth of well 190 can be commensurate with the thickness of covering layer 120, or less. Preferred depths of well 190 can typically be from 0.5 to 50 micrometers, with a preferred depth of at least 3 micrometers. Deeper wells are also contemplated including wells having depths of 10, 20, 30 micrometers, or more. The dimensions of the exposed surface of bond pad 110 can be adjusted to fit a desired solder bump. One should note that well depth can affect a desired minimum exposed surface of bond pad 110 for a target solder bump. Typically, the exposed area of bond pad 110 is circular with typical diameters in the range from 25 to 1500 micrometers, with a preferred range from 50 to 1250 micrometers.

Once a target substrate 100 is provided, a work space is configured to operate on substrate 100 to form solder bumps. In a preferred embodiment, the work space is configured to allow solder bump formation without use of masking steps. As will become evident below, masking features of substrate 100 is not required.

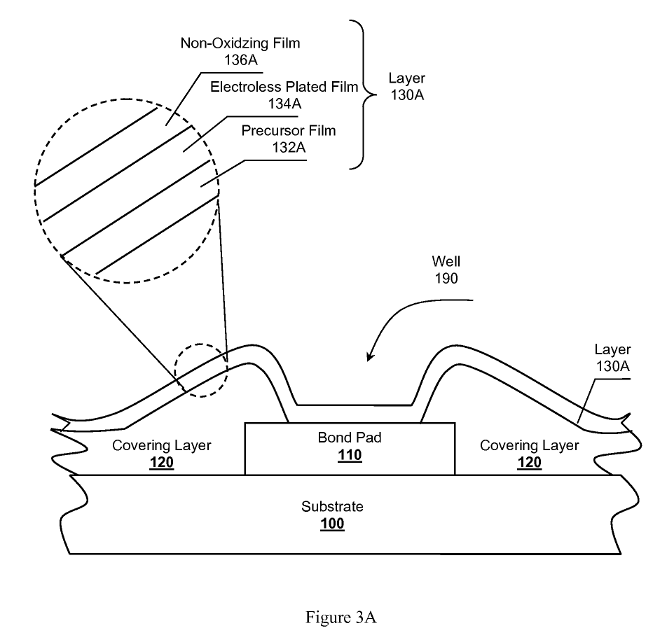

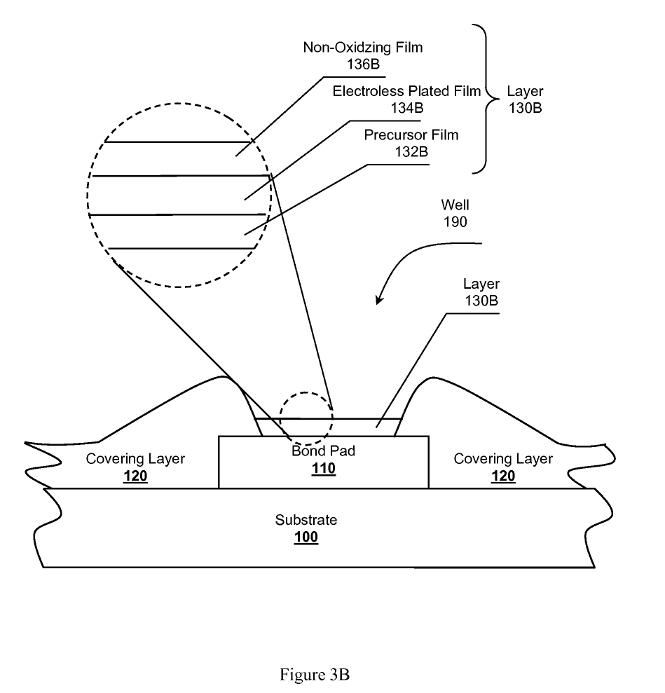

FIG. 3A presents a cross sectional view where an intermediary layer comprising an under bump metallization (UBM) layer 130A is deposited over at least the exposed surface of bond pad 110 at the bottom of well 190. Metallization layer 130A can provide a strong electrical and mechanical contact between bond pad 110 and subsequently placed materials that are deposited over layer 130A. In a preferred embodiment, layer 130A comprises one or more films as shown in the inset. Preferably layer 130A comprises at least precursor film 132A in direct contact with bond pad 110. Precursor film 132A can comprise Palladium (Pd), Platinum (Pt), or other metals that bond with bond pad 110. Metallization precursor film 132A preferably substantially comprises Pd or Pt (e.g., more than 95% pure, and more preferably more than 99% pure). It is also contemplated layer 130A can comprise additional metallization films. For example, layer 130A could also comprise films of Gold (Au), Silver (Ag), Nickel (Ni), Tin (Sn), or other metals or their alloys. In a preferred embodiment, layer 130A comprises a precursor film 132A of a precursor material of about 50 to 200 Angstroms thick in contact with bond pad 110, a second film 134A of an electroless plated material preferably Ni of about 2000 to 5000 Angstroms thick deposited on the film 132A, and a third film 136A of a non-oxidizing cap of Au or Ag of about 500 Angstrom over the film 134A.

Preferably precursor film 132A is deposited by spraying a coating comprising the metallization precursor material into well 190, or by dipping substrate 100 into a bath having the film precursor material. In such embodiments, film 132A can be cured at a low temperature of less than 400 degrees Celsius, more preferably less than 150 degrees Celsius, and yet more preferably less than 90 degrees Celsius to force the precursor material to adhere to bond pad 110. A second film 134A of metallization layer 130A can be deposited by an electroless plating step after curing the precursor material. Remaining films (e.g., non-oxidizing film 136A) can be also deposited using known techniques. It is also contemplated that other methods can be employed to deposit various other films of metallization layer 130A including chemic vapor deposition, plasma-enhanced chemical vapor deposition, sputtering, or other techniques. One should note that the use of masking is not required or necessary to properly place layer 130A. In fact, in some embodiments, layer 130A is can be deposited across substantial portions of the exposed native surfaces of substrate 100.

Although FIG. 3A illustrates metallization layer 130A as a single layer, one should appreciate that multiple films (e.g., 132A, 134A, 136A, etc.) could be deposited to form UBM layer 130A as shown in the inset. For example, layer 130A could include additional films to provide better adhesion, or to prevent undue oxidation as discussed above.

FIG. 3B illustrates a cross section view of an alternative step for applying a metallization layer 130B. Layers 130A and 130B are collectively referred to as metallization layers 130, as both represent a UBM layer. In this example shown, a solvent comprising the precursor material is preferably tuned to only wet the material of bond pad 110, but not to wet the material of covering layer 120. This approach provides for placing precursor film 132B only at the bottom of well 190 on an exposed surface of bond pad 110. Depositing additional films (e.g., an electroless plating film 134B, or a non-oxidizing cap 136B) can use a similar technique. Such an approach virtually eliminates the precursor material, or other film materials, from adhering to covering layer 120, and eliminates a need to remove metallization material for surfaces external to well 190.

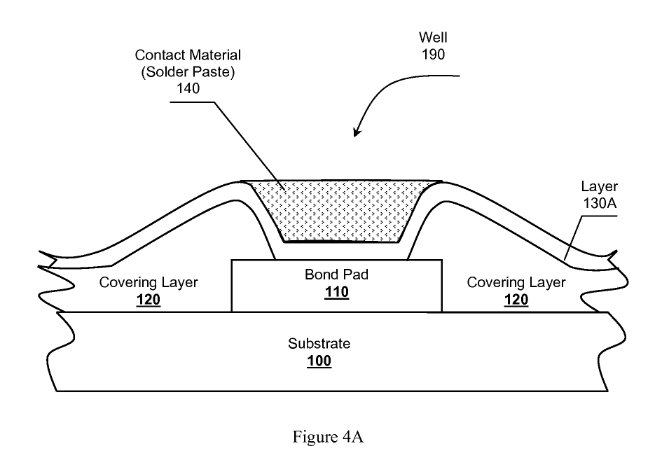

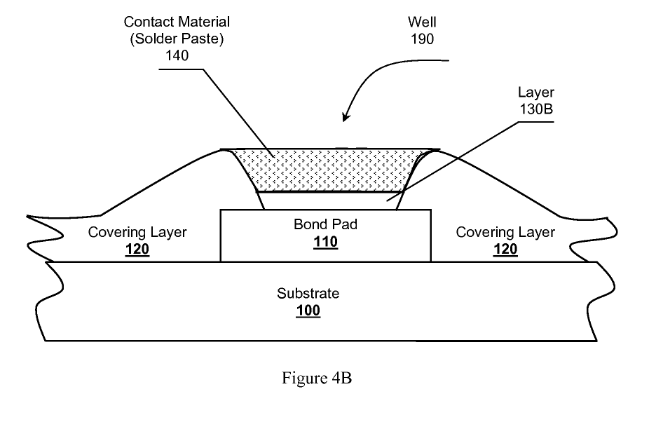

FIG. 4A also presents a cross sectional view where contact material 140 is deposited within well 190 in a manner were contact material 140 is in electrical contact with bond pad 110, possibly via one or more films of UBM layer 130A. Contact material 140 is intended to provide a contact point for a prepared solder ball. In a preferred embodiment contact material comprises a solder paste (e.g., Pb/Sn). The solder paste is preferably deposited within well 190, and is deposited approximately up to the wall height of well 190. Excesses of contact material 140 outside of well 190 can be removed easily after reflowing, or by planarizing the surfaces. Contact material 140 can be deposited in well 190 using known techniques including using a squeegee to push contact material 140 into well 190. One should note that the walls of well 190 remains in place during processing, where traditional approaches remove a solder bump mold. FIG. 4B presents an embodiment where metallization layer 130B has only to be deposited on the exposed surface of bond pad 110, and where contact material 140 is contained by the walls of well 190.

In some embodiments, UBM layer 130A or 130B can function as contact material 140. For example, in embodiments where well 190 has a depth of 3 to 10 micrometers, it is thought that UBM layer 130A or 130B would be sufficient to contact to a prepared solder ball. In embodiments having deeper wells (e.g., greater than 10 micrometers), it is thought that solder paste serves well as contact material 140.

One should appreciate that in embodiments where solder paste is employed, the amount of solder paste deposited need not be strictly controlled. For example, less paste than required to fill well 190 could be deposited in well 190. When reflowed, the paste would form a solder tab where the surface of the tab at the top portion of well 190 could have a concaved depression. Excess paste on surfaces external to well 190 can then be removed by subsequent steps including through planarizing the surfaces of substrate 100 as discussed below.

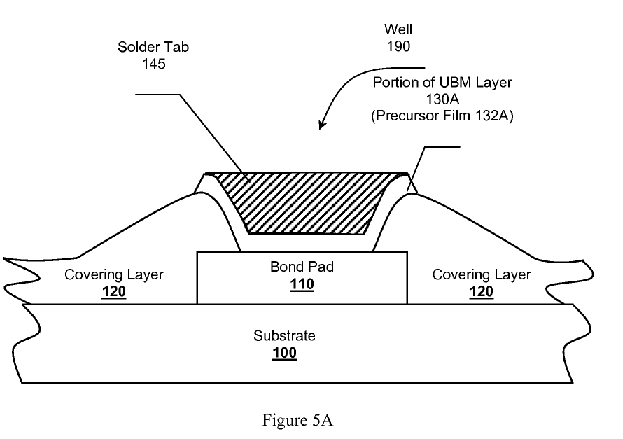

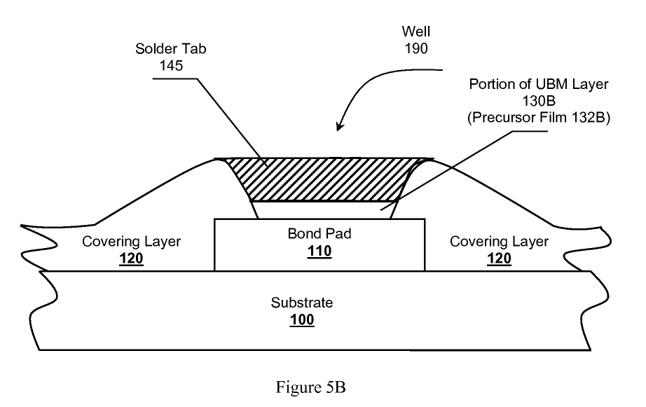

In FIG. 5A, contact material 140 can be reflowed if necessary, preferably at a low temperature in the range from 150 to 400 degrees Celsius, and more preferably at or below 300 degrees Celsius. The reflowing preferably does not form a solder bump. Rather, reflowing causes contact material 140 to fill well 190, and to bond to the exposed surfaces of bond pad 110, or to exposed surfaces of layer 130A deposited on bond pad 110 or walls of well 190. After reflowing, contact material 140 forms a solid, solder tab 145 that has strong electrical contact with bond pad 110. Solder tab 145 can have a substantially flat surface across the top of well 190 as shown, or have a concave surface with a slight depression. In other embodiments, reflowing can occur after placing a solder ball on contact material 140. In the following discussion, one should appreciate that solder tab 145 is simply contact material 140 after reflowing. One should also note that stating “a solder ball comes into contact with a contact material 140” is considered equivalent to “a solder ball comes into contact with solder tab 145” with respect to the discussion below.

FIG. 5A illustrates, in cross section, film 132A and tab 145 as being distinct for clarity purposes. One should note that one or more films of layer 130A could be consumed into tab 145 as a result of reflowing. In a preferred embodiment, capping material (e.g., Au, Ag, etc.), and at least a portion electroless plating material (e.g., Ni, etc.) are consumed by solder tab 145 during reflow, while the precursor film 132A can remain at least partially intact.

Excesses of metallization layer 130A can be removed from external surfaces around well 190, preferably once reflow has been completed. This can be achieved by known wet etch techniques applied before or after placing of a solder ball. Again, no masking of the surface is required.

In more preferred embodiments, substrate 100 can be planarized by grinding down exposed surfaces to remove UBM layer 130A. Planarization can occur before or after depositing contact material 140, or before or after reflowing of contact material 140. In such embodiments, covering layer 120 operates as an etch stop to indicate when planarization should be stopped. Planarization can be conducted by simply grinding the surfaces of substrate 100 using finer and finer grit polish using establishing techniques. Planarizing the surfaces of substrate 100 can also be used to ensure that multiple wells 190 on substrate 100 have uniform depths. Such an approach aids in providing solder bumps having a high degree of uniformity in their heights.

FIG. 5B illustrates an alternative approach where layer 130B is only deposited on an exposed surface of bond pad 110 at the bottom of well 190. In such embodiments, the step of removing excess metallization layer 130B is not necessary. Furthermore, the precursor film 132B (e.g., Pd, Pt, etc.) can remain substantially intact after reflow of contact material 140. Upper films of layer 130B can be at least partially consumed by reflowing to form solder tab 145.

In some embodiments, at least some of preceding steps illustrated up through FIGS. 5A and 5B can be repeated as necessary to ensure the surfaces of substrate 100 are properly prepared. For example, substrate 100 depicted in FIG. 5A could be planarized as discussed above, then cleansed. Additional contact material 140 can be spread over the surfaces to ensure that all wells 190 are indeed filled. The contact material 140 can be reflowed again, and planarized again. It is thought that repeating the steps two or three times is sufficient to achieve at least a 95% yield, or more preferably at least a 99% yield.

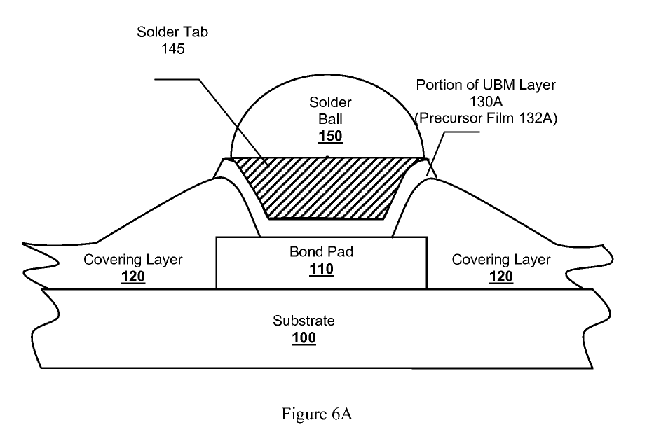

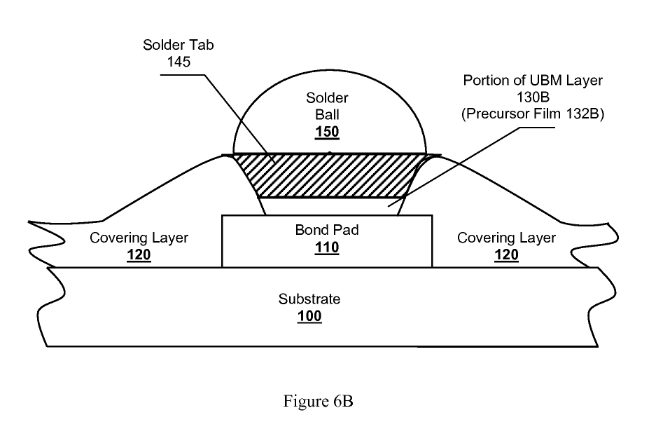

In FIGS. 6A and 6B, again in cross section view, an a priori prepared solder ball 150 has been placed or transferred to solder tab 145 to form a desired solder bump. As used herein, “a priori prepared solder ball” is used to mean that the material to form a solder ball has been prepared separately, preferably in parallel to decrease processing times, from preparing substrate 100 and requires no further active steps to shape solder ball 150. An a priori prepared solder ball 150 can include a solder ball that is in a solid form, or a drop of liquid or molten solder that cools to form solid ball 150. It should be appreciated that an a priori prepared solder ball has an approximate ball-shape when placed. However, a solder paste is not considered an a priori prepared solid ball because it requires an extra step of reflowing to cause the paste to reflow and to form a sphere shape, unless already formed into a balls shape. “Ball shape” and “sphere shape” should be considered to include approximate sphere or hemispherical shapes as well. Otherwise the solder paste retains it deposited shape. Although a preferred embodiment employs an a priori prepared solder ball, one should appreciate that the disclosed technique can also be applied to solder balls comprising a solder paste that can eventually be reflowed to form a ball shape.

FIG. 6A represents an example where a metallization layer 130A has been applied over covering layer 120, and where a portion of UBM layer 130A remains intact. FIG. 6B represents an example where metallization layer 130B has only be applied to an exposed surface of bond pad 110 at the bottom of well 190, and where a portion of UBM layer 130B remains intact.

One or more of solder ball 150 can be placed directly on contact material 140 before reflow, or directly on solder tab 145 after contact material 140 has been reflowed. One acceptable method of placing solder ball 150 includes placing solid-preformed solder balls using a solder ball drop process. Another acceptable method includes placing solder ball 150 in a liquid or molten form on contact material 140 or solder tab 145. In either case, solder ball 150 can be bonded to the underlying contact material 140 by heating solder ball 150 and contact material 140, if necessary, in a manner where the ball forms an integral bond with the material. When solder ball 150 is in a molten form, its own heat can cause it to bond to solder tab 145.

One should keep in mind that the disclosed processes for attaching solder ball 150 to solder tab 145 can be applied across a plurality of bond pads 110 and their associated wells 190.

In a preferred embodiment, a plurality of solder balls 150 is placed substantially at the same time. This can be achieved by adapting techniques developed by Spheretek LLC Division of MVM Technologies, Inc., of Sunnyvale Calif., as described in U.S. Pat. No. 7,007,833 titled “Forming Solder Balls on Substrates” (March 2006). A solder ball template can be created having solder balls held in cells of the template, where the balls can be arranged in a pattern that mirrors that of the wells 190 on substrate 100. In a preferred embodiment, the solder ball template comprises cells that hold liquid or molten solder, where the arrangement of the template cells mirror the arrangement of wells 190 on target substrate 100. The solder ball template can then be juxtaposed with substrate 100 and wells 190 in a manner where one or more of the liquid solder balls 150 in their cells contact solder tabs 145 in wells 190. The heat of the molten solder balls causes the solder balls 150 to transfer to their corresponding wells 190 due to the ball's interference fit in the cells, and to form a solder bump. One should note that no masking of the substrate is required. It should be appreciated that preparing solder balls 150 separately from processing substrate 100 allows for a parallel work flow that decreases processing time in solder ball formation.

Also of note is that using a template provides a great deal of control over the solder ball formation. The solder balls can be formed to have a high degree of uniformity with the respect to one, two, or more characteristics (e.g., volume, footprint, width, weight, height, sphericity, etc.), where 99% of the balls have a measured characteristic that falls within five percent of a target specification for the characteristic, more preferably within two percent, yet more preferably within one percent, and even yet more preferably within 0.1 percent of the target specification. Additionally, it should be appreciated that using templates allows for forming homogeneous or heterogeneous arrays of solder balls.

Preferred solder balls 150 are produced to have a uniform sphericity to within a tolerance down to ±10 micrometers, or more preferably down to ±5 micrometers. Additionally, preferred solder balls 150 can have diameters in the range from 25 to 1500 micrometers, or more preferably from 50 to 1250 micrometers. Preferably solder balls 150 comprise Pb, Pb/Sn, or other metallurgies. Acceptable solder balls can be obtained from MVM Technologies Inc., of San Clemente, Calif. One should note that the solder balls 150 placed on substrate 100 can also be of a heterogeneous sizes or dimensions. In fact, each cell in a solder ball template could be of different sizes or dimensions from other cells of the template.

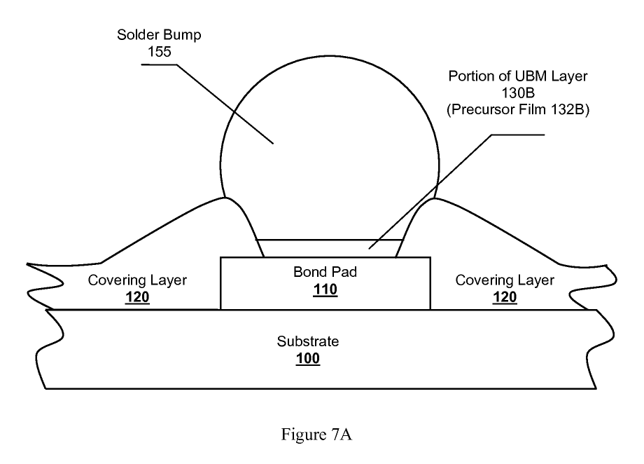

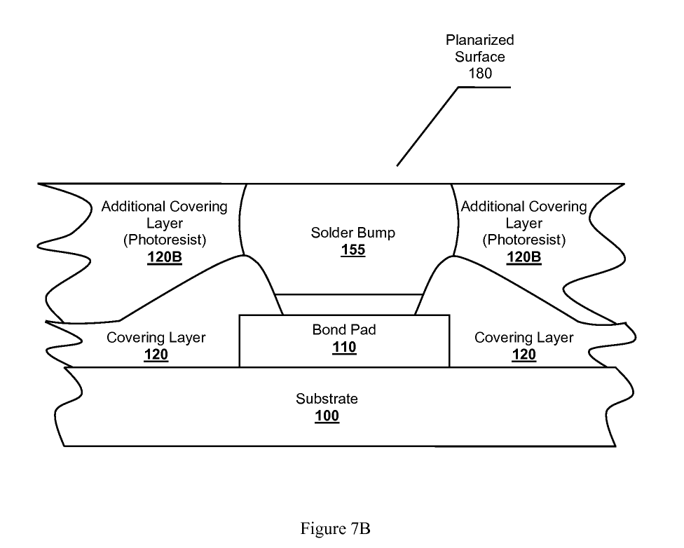

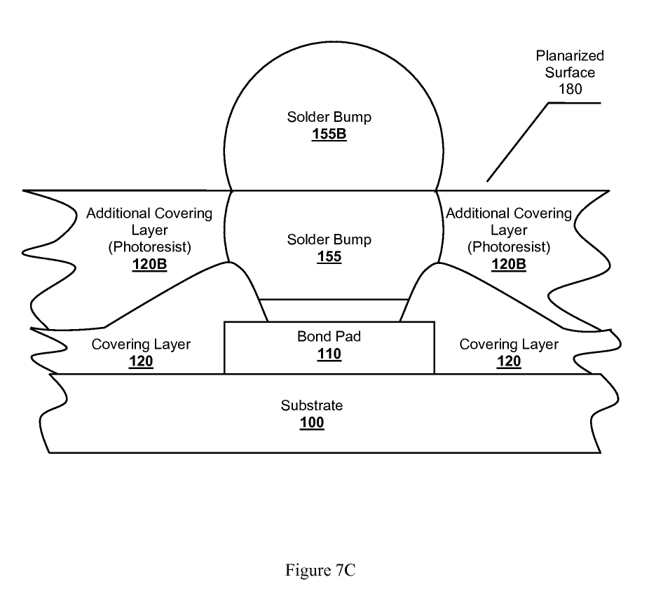

FIG. 7A, presents a cross sectional view of one embodiment of solder bump 155 formed by the above described process. In some embodiments, solder ball 150, solder tab 145, or portions of metallization layer 130 to form a single integral solder bump 155 after a possible final stage of reflowing or heating. Some portions of layers 130A or 130B (e.g., films 132A or 132B respectively) can remain intact. An optional reflow step can be performed if desired to ensure solder bump 155 has a desirable shape. Again, one should appreciate that solder bump 155 can be formed without use of photoresist or masking applied to substrate 100.

FIG. 7B, presents a possible embodiment where one or more of steps of the disclosed solder bump production process are repeated. One or more additional covering layers 120B have been deposited on substrate 100, where the covering material can surround solder bump 155. Additionally, the surfaces can be planarized to level the surface, exposing a portion of solder bump 155 and forming planarized surface 180. Planarized surface 180 can be a work surface or additional processing. Additionally covering layer 120B can act like an etch stop during planarization. In fact, solder bump 155 can function as solder tab 145, or even bond pad 110 during the additional processing.

In FIG. 7C, additional solder bump 155B has been placed on planarized solder bump 155 of FIG. 7B. If desired, solder bump 155B and 155 can be reflowed so they become integrally bonded. Additional covering layer 120B can be removed. For example, if covering layer 120B comprises photoresist, the photoresist can be removed using known techniques, leaving behind a tall solder bump having a desired height, or other characteristic. One should appreciate that no masking was used to form solder bump 155B, and that the repetition of planarizing or depositing additional covering layer 120B provides for creating a broad spectrum of geometries or topologies of solder bumps.

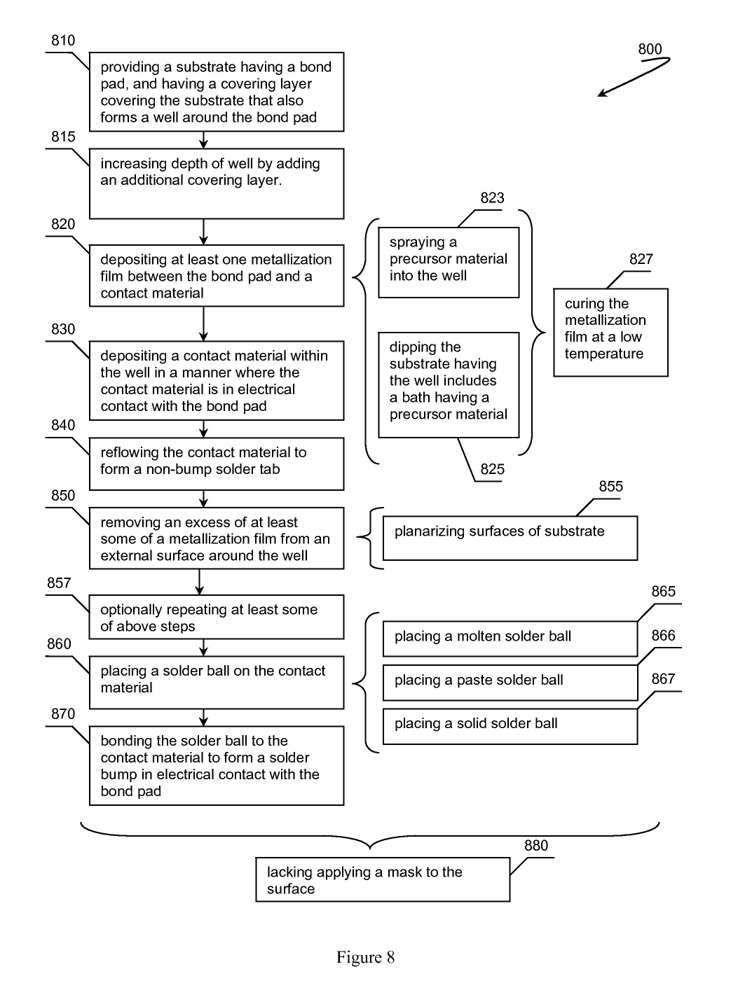

FIG. 8 presents an overview of method 800 of forming one or more solder bumps without using a photoresist processing or masking as discussed above. In a preferred embodiment, a plurality of solder bumps is formed on the substrate substantially at the same time.

At step 810, a substrate, preferably a wafer, is provided having one or more bond pads. Preferably the substrate is the result of a standard IC manufacturing process, and has an existing covering layer. In some embodiments, the bond pads are arranged on the wafer in regular repeating patterns, and in other embodiments the bond pads are arranged irregularly. The substrate preferably has a covering layer covering surfaces of the substrate and that also forms wells around bond pads disposed on the substrate, where the bond pads retain exposed surfaces at the bottom of the well.

In some embodiments, additional covering layer material is deposited to ensure wells have desired depths at step 815. Additional layers can be added by using similar techniques as used for depositing an initial layer. In some embodiments, the additional layers can comprise photoresist which can be subsequently removed as desired.

At step 820, an UBM layer can be deposited on top of the covering layer, or in the wells of the bond pads where the UBM layer covers exposed surfaces of the bond pads. In a preferred embodiment, the UBM layer comprises at least one metallization film. The layer can comprise one or more films including an adhesion film of a precursor material, a film of an electroless plating material, or a film of a capping material. Preferred precursor films comprise a Pd or a Pt precursor material that contacts the bond pad directly. The UBM layer provides electrical contact between the contact pad and other materials deposited within the well. At step 823, a precursor film can be deposited via spraying a precursor material into at least the wells of the bond pads, or at step 825 the substrate can be dipped into a bath having the precursor material in solvent form. In preferred embodiments, the solvent only wets material of the bond pad and does not wet or adhere to the covering layer. At step 827 the precursor film can be cured, preferably at a low temperature of less than about 150 degrees Celsius, or more preferably at less than about 90 degrees Celsius.

At step 830 a contact material is deposited in the wells. In some embodiments, a UBM layer functions as the contact material. In other embodiments, a solder paste is used as a contact material. For example, solder paste can be placed within the wells, and fills the wells substantially to the top of the well walls. The contact material can be deposited using known techniques including spreading the contact material via squeegee, or using PCB stenciling techniques. Contact material external to the well can be easily removed after reflowing by washing the substrate, or through planarization (see also step 855).

Preferred solder paste has small particle size relative to the dimensions of the target wells. Small sized particles reduce a risk of having voids in the well, or having non-intimate contact with the UBM layer. Preferred solder paste has particles of less than about 25 micrometers in size, more preferably less than about 15 micrometers, and yet more preferably less than 12 micrometers.

As step 840 the contact material is preferably reflowed to form a solder tab, preferably a non-bump solder tab. In a preferred embodiment, the solder tabs comprises an approximately level surface across a top portion of a bond pad well, or even a concave surface across the top of the well in a depression. One should appreciate that the disclosed techniques have a high degree of tolerance with respect to the amount of contact material deposited into the wells. In preferred embodiments, as shown, step 840 is performed before attaching a solder ball. In other embodiments, step 840 can be performed after attaching a solder ball. In some embodiments, a precursor film material of the under bump metallization layer can remain substantially intact. Such an approach ensures that a solid, strong, electrical contact is made between the solder tab and the bond pad.

At step 850, preferably after step 840 and if necessary, excess UBM layer material can be removed from surfaces external to bond pad wells. In some embodiments, the excess material can be removed by wet etching. In other embodiments, at step 855, the excess material can be removed by planarizing the surfaces of the target substrate as discussed above. The surfaces can be planarized by polishing the surfaces using finer and finer grit abrasives, preferably until the covering layer is reached. As previously discussed, planarization removes excess material as well as ensures that multiple wells have uniform heights.

At optional step 857, one or more of the above steps can be repeated to ensure all wells are prepared properly. Repeating the steps can increase the yield of the overall process. For example, after reflowing, if some wells are revealed to have voids, gaps, or lack contact material, then additional contact material can be deposited to fill gaps, reflowed again, and planarized again. It is contemplated that repeating one or more of the steps two, three, or more times is sufficient to results in yield of greater than 99%. In fact, it is also contemplated that repeating the steps is of sufficient value that repeating the steps can be made as a standard part of the process.

At step 860, an a prior prepared solder ball can be placed on the contact material. The solder ball maintains electrical contact with the underlying bond pad via the contact material (e.g., a solder tab, or UBM layer). A prepared solder ball, either in liquid or solid form, preferably contacts the surface of the contact material, even if the surface of the contact material has a concave surface or has a depression in to the well. The curve of the ball extends into the depression of the concave surface until contact is achieved.

One method for placing a prepared solder ball is described at step 865. Solder balls can be placed in the wells of a target substrate by utilizing a template having cells that hold the solder balls in liquid or molten form. The template's solder ball cells are preferably arranged in a pattern that mirrors the patterns of the wells on the target substrate. The template can be moved into a juxtaposed position with the target substrate, where the solder balls contact the contact material in the wells of the target substrate. As discussed in U.S. Pat. No. 7,007,833, the molten solder balls extend slightly from their cells due to an interference fit, and can wet the contact material of the wells even if the wells have a depressed concave surface.

At step 866, it is also contemplated that solder balls in the form of a solder paste can be placed on the contact material. For example, using the template technique described above with respect to step 865, the cells of the template can be filled with solder paste. When the template is placed in a juxtaposed position with a target substrate, the assembly can be heated to reflow the paste in the cells of the template. The cell's reflowed solder balls contacts the contact material in the wells of the target template and bonds with the contact material.

Another acceptable method for placing a prepared solder ball is shown as step 867. At step 867, solid solder balls are placed using any acceptable method including a solder ball drop process. Other techniques for placing solid balls can also be used.

At step 870, solder balls contact with the solder tab in the wells, and bonds to the solder tab. In embodiments using molten solder balls, the solder balls bond via the temperature of the molten solder material. Alternatively, the target substrate having solid solder balls can be heated, if necessary, to reflow the contact material, possibly a second, third, forth, or more times, to bond the solder balls to the wells. The result is that the wells have solder bumps that are tightly coupled to, and in strong electrical contact with the bond pads of the wells.

It is also contemplated that once solder balls are formed on the target substrate, the ball array could be optionally planarized to ensure that all balls have uniform heights, or desired topologies. Once planarized, the balls can be reflowed again, if necessary to restore the balls to sphere shape.

At step 880, it should be noted that method 800 is conducted while lacking a step of applying a mask to surfaces of the substrate.

One should appreciate there are numerous advantages due to the disclosed techniques including:
a. No masking is required
b. Excellent bump strength is created because the bump is attached to a solder tab. The solder tab can be supported by tall sides of the covering layer (e.g., a polyimide passivation edge) as well as by the precursor material attached to the bond pad metal.
c. The disclosed technique for placing a precursor film is not an electroless plating process for bonding the precursor material to the underlying bond pad, and forms a stronger bond between the precursor metallization film and the bond pad metal when compared to a Zincate process.
d. The disclosed technique can be a direct replacement for a Zincate process.
e. Through the use of a priori preformed solder balls, either in liquid solder form or in solid form, results in highly precise placement of solder bumps with tight tolerance.
f. When using a solder ball template, time is saved by forming many solder bumps essentially at the same time, and by preparing solder balls in parallel to substrate processing.
g. A solder bump or solder bumps produced using the disclosed techniques allows for creating a solder bump that conforms closely to a desired tolerance or creating solder bumps that have a high degree of uniformity with respect to each other.

It should be apparent to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A method of forming a solder bump on a substrate, the method comprising:
providing a substrate having a bond pad, and having a covering layer that covers the substrate and that also forms a well around the bond pad;
depositing a contact material within the well in a manner where the contact material is in electrical contact with the bond pad;
placing an a priori prepared solder ball on the contact material; and
bonding the solder ball to the contact material to form the solder bump, where the solder bump is in electrical contact with the bond pad.

2. The method of claim 1, further comprising depositing at least one metallization film of a precursor material between the bond pad and the contact material.

3. The method of claim 2, wherein the precursor material comprises at least one of Palladium and Platinum.

4. The method of claim 2, wherein the step of depositing the at least one metallization film includes spraying the precursor material into the well on an exposed surface of the bond pad.

5. The method of claim 2, wherein the step of depositing the at least one metallization film includes dipping the substrate having the well into a bath comprising the precursor material, where the precursor material contacts an exposed surface of the bond pad.

6. The method of claim 2, further comprising removing an excess of the at least one metallization film from an external surface around the well.

7. The method of claim 1, wherein the covering layer comprises a passivation material selected from a group consisting of: a polyimide, a glass, and a nitride.

8. The method of claim 1, wherein the covering layer comprises a photoresist material.

9. The method of claim 1, further comprising increasing a depth of the well by adding an additional covering layer.

10. The method of claim 9, wherein the additional covering layer comprises a photoresist material.

11. The method of claim 1, wherein the contact material comprises a solder paste.

12. The method of claim 1, wherein the contact material comprises an under bump metallization layer.

13. The method of claim 1, further comprising reflowing the contact material to form a non-bump solder tab.

14. The method of claim 13, wherein the step of reflowing occurs before the step of placing the solder ball.

15. The method of claim 13, wherein the step of reflowing occurs after the step of placing the solder ball and results in an integral bond between the solder ball and the contact material.

16. The method of claim 13, wherein the step of reflowing consumes a first portion of an under bump metallization layer deposited between the contact material and the bond pad, and leaves a second portion of the under bump metallization layer intact.

17. The method of claim 1, wherein the step of placing the solder ball includes using a template having cells arranged to mirror a well pattern on the substrate, where at least some of the cells hold a molten prepared solder ball.

18. The method of claim 1, wherein the step of placing the solder ball includes using a template having cells arranged to mirror a well pattern on the substrate, where at least some of the cells hold a prepared solder paste.

19. The method of claim 1, further comprising planarizing exposed surfaces on the substrate.

20. A method of forming a solder bump on a substrate, the method comprising:
providing a substrate having a bond pad, and having a covering material that covers at least some of a surface of the substrate and that also forms a well around the bond pad;
depositing a contact material within the well in a manner where the contact material is in electrical contact with an exposed surface of the bond pad at the bottom of the well;
reflowing the contact material to form a solder tab within the well;
planarizing exposed surfaces on the substrate to create an approximately level surface on the solder tab at a top portion of the well;
placing an a priori prepared solder ball on the solder tab in the well; and
bonding the solder ball to the contact material to form the solder bump, where the solder bump is in electrical contact with the bond pad.

21. The method of claim 20, further comprising repeating the steps of depositing the contact material, reflowing the contact material, and planarizing expose surfaces at least once.

22. The method of claim 21, further comprising repeating the steps of depositing the contact material, reflowing the contact material, and planarizing exposed surfaces at least twice.

23. The method of claim 20, further comprising depositing an under bump metallization layer material before depositing the contact material.

24. The method of claim 23, wherein the step of planarizing exposed surfaces includes removing excess of the under bump metallization layer material from surfaces external to the well.

25. The method of claim 20, wherein the covering material comprises photoresist.

26. The method of claim 20, further comprising increasing a depth of the well by depositing an additional layer of a covering material around the well.
